(19) United States
(12) Patent Application Publication
(10) Pub. No.: US 2026/0068331 A1
(43) Pub. Date: Mar. 5, 2026

(54) VERTICAL DIODE UTILIZING BACKSIDE POWER DELIVERY NETWORK

(71) Applicant: INTERNATIONAL BUSINESS MACHINES CORPORATION, ARMONK, NY (US)

(72) Inventors: Robert Gauthier, Williston, VT (US); Ruilong Xie, Niskayuna, NY (US); Anindya Nath, Watervliet, NY (US); Masoud Zabihi, Schenectady, NY (US); Anthony I-Chih Chou, Guilderland, NY (US)

(21) Appl. No.: 18/818,533

(22) Filed: Aug. 28, 2024

(51) Int. Cl. H01L 27/02; H01L 21/768; H01L 23/528; H01L 29/06; H01L 29/417; H01L 29/66; H01L 29/739

(52) U.S. Cl. CPC H10D 89/921; H10D 12/021; H10D 12/211; H10D 62/116; H10D 64/252

(57) ABSTRACT

A semiconductor device can include a backside contact over a backside power delivery network (BSPDN), a first doped region over the backside contact, a well region over the first doped region, a second doped region over the well region, and gate regions surrounding the well region.

### BACKGROUND

### Technical Field

The present disclosure generally relates to semiconductors, and more particularly, to semiconductors with sidewall connection to the backside power delivery network structure, and methods of creation thereof.

### Description of Related Art

The relentless miniaturization of transistors and their increasing density on chips epitomize the semiconductor industry's innovation, largely adhering to Moore's Law. This trend has led to transistors shrinking to nanometer scales, allowing millions and even billions to fit on a single chip, significantly enhancing computational power and energy efficiency. The evolution towards system-on-chip architectures integrates various functionalities, including processing and sensing, on one chip.

### SUMMARY

According to an embodiment, a semiconductor device includes a backside contact over a backside power delivery network (BSPDN), first doped region over the backside contact, a well region over the first doped region, a second doped region over the well region, and gate regions surrounding the well region.

In one embodiment, the semiconductor device includes a spacer layer surrounding the second doped region.

In one embodiment, the semiconductor device includes shallow trench isolation (STI) surrounding the backside contact and the first doped region.

In one embodiment, the STI includes an STI oxide layer surrounded by an STI liner.

In one embodiment, the STI is isolated from contact with the gate regions via a spacer layer.

In one embodiment, the semiconductor device is a vertical diode.

In one embodiment, the semiconductor device includes a back end of line (BEOL), and the BEOL is connected to the second doped region via a contact and frontside power wirings.

According to an embodiment, a method for fabrication of a semiconductor device includes forming a backside contact over a backside power delivery network (BSPDN), forming first doped region over the backside contact, forming a well region over the first doped region, forming a second doped region over the well region, and forming gate regions surrounding the well region.

In one embodiment, the method includes forming a contact over the second doped region, forming frontside power wirings over the contact, forming a back end of line (BEOL) over the frontside power wirings, and establishing an electrical connection between the second doped region and the BEOL via the contact and the frontside power wirings.

In one embodiment, the method includes surrounding the second doped region via a spacer layer.

In one embodiment, the method includes surrounding the backside contact and the first doped region via shallow trench isolation (STI).

In one embodiment, the STI includes an STI oxide layer surrounded by an STI liner.

In one embodiment, the method includes isolating the STI from contact with the gate regions via a spacer layer.

According to an embodiment, a semiconductor device includes a first vertical diode, a second vertical diode adjacent to the first vertical diode on a first side, and a third vertical diode adjacent to the second vertical diode on a second side,

In one embodiment, the first vertical diode and the second vertical diode are electrically connected via a first backside power delivery network (BSPDN), and the second vertical diode and the third vertical diode are electrically connected via a first frontside power wiring.

In one embodiment, each of the first vertical diode, the second vertical diode and the third vertical diode includes a first doped region over a backside contact, a well region over the first doped region, a second doped region over the well region, and gate regions surrounding the well region.

In one embodiment, the each of the first vertical diode, the second vertical diode and the third vertical diode includes a spacer layer surrounding the second doped region.

In one embodiment, each of the first vertical diode, the second vertical diode and the third vertical diode includes shallow trench isolation (STI) surrounding the backside contact and the first doped region.

In one embodiment, the semiconductor device includes an STI oxide layer surrounded by an STI liner, the STI is isolated from contact with the gate regions via a spacer layer.

In one embodiment, the first vertical diode further includes a second frontside power wiring, and the third vertical diode further includes a second BSPDN.

In one embodiment, the first frontside power wiring and the second frontside power wiring are isolated by an interlayer dielectric (ILD), and the first BSPDN and the second BSPDN are isolated by the ILD.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIG. 1 illustrates a conventional nanosheet string diode with guardrings.

FIGS. 2A-2B illustrate a semiconductor device, in accordance with some embodiments.

FIG. 3 illustrates a semiconductor device after the preparation of the starting wafer, in accordance with some embodiments.

FIG. 4 illustrates a semiconductor device after the formation of the fins, in accordance with some embodiments.

FIG. 5 illustrates a semiconductor device after the formation of the sidewall spacer, in accordance with some embodiments.

FIG. 6 illustrates a semiconductor device after the formation of the first doped regions, in accordance with some embodiments.

FIG. 7 illustrates a semiconductor device after the patterning of the active regions, in accordance with some embodiments.

FIG. 8 illustrates a semiconductor device after the formation of shallow trench isolation, in accordance with some embodiments.

FIG. 9 illustrates a semiconductor device after the formation of the gate regions, second doped regions, middle of line processes, and back end of line processes, in accordance with some embodiments.

FIG. 10 illustrates a semiconductor device after the removal of the first substrate, in accordance with some embodiments.

FIG. 11 illustrates a semiconductor device after the removal of the etch estop layer, in accordance with some embodiments.

FIG. 12 illustrates a semiconductor device after the formation of the backside contact, in accordance with some embodiments.

FIG. 13 illustrates a semiconductor device after the formation of the backside interconnect, in accordance with some embodiments.

FIG. 14 illustrates a block diagram of a method for forming the semiconductor device, in accordance with some embodiments.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or logical changes may be made without departing from the spirit and scope defined by the claims. The description of the embodiments is not limiting. In particular, elements of the embodiments described hereinafter may be combined with elements of different embodiments.

A diode-connected transistor is a configuration where the base and collector of a bipolar junction transistor, or BJT, are connected together. This type of connection changes the behavior of the transistor so it acts more like a diode. In this arrangement, the collector and base are directly linked, essentially merging two of the three terminals of the BJT, which leaves the emitter and the combined base-collector as the only active connections. When voltage is applied across these points, it encourages current to flow from the emitter to the base in typical BJT fashion. However, because the collector is also attached to the base, the transistor is not able to amplify current. This is because the device cannot differentiate between the input and output signals, preventing it from functioning as an effective amplifier. The current that flows resemble that in a forward-biased diode, flowing easily in one direction and offering significant resistance in the other. This similarity gives the setup its name. The behavior of the diode-connected transistor is useful because the voltage drop across the base-emitter junction is stable, usually about 0.7 volts for silicon transistors, much like a regular diode.

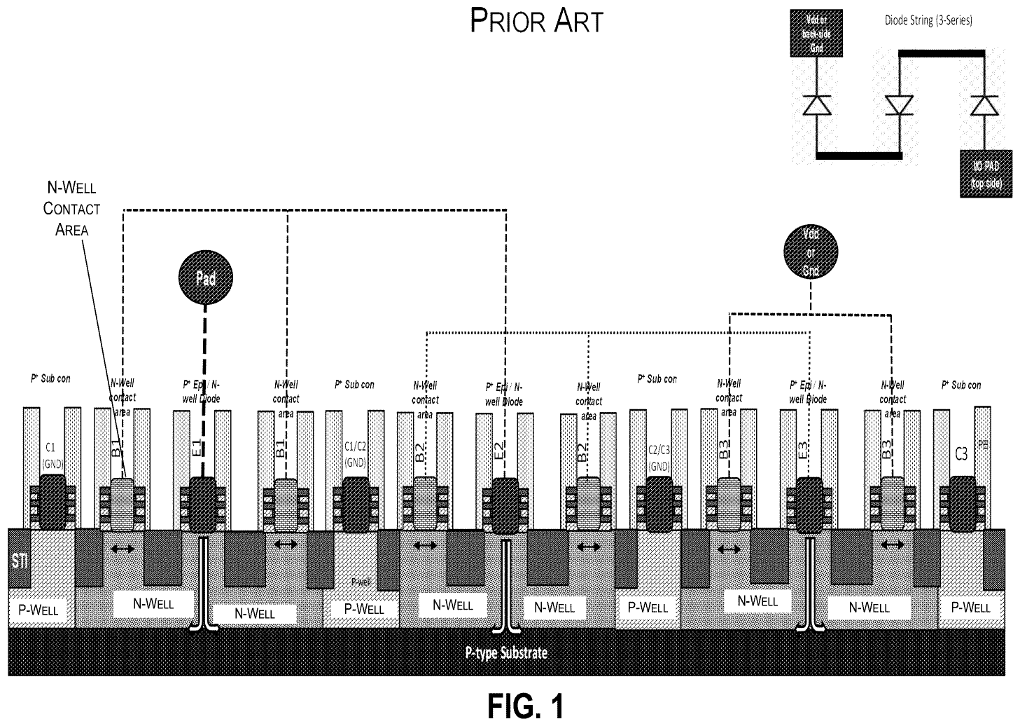

The use of nano-sheet p-doped/n-well/P-well, P+/NW/PW, string diodes with P-well guardrings, as shown in FIG. 1, is a conventional strategy employed to prevent latch-up in semiconductor devices. Latch-up is a type of short circuit that can occur within an integrated circuit, leading to device failure. The P+/NW/PW diode strings act as protective barriers by managing and directing current flow, while P-well guardrings enhance the isolation between different components of the circuit, further mitigating the risk of electrical interference and latch-up.

However, as the demand for more compact and densely packed electronic devices grows, the space occupied by these components becomes a significant concern. Traditional horizontal layouts increasingly struggle to meet the stringent space requirements of modern high-density circuits, prompting a shift towards more space-efficient designs.

In view of the above considerations, disclosed is a semiconductor device including a diode-connected transistor with utilizing vertical field-effect transistor (vFET) architectures with backside power delivery network (BSPDN). This approach leverages the vertical dimension of semiconductor devices, rather than expanding horizontally, thus saving valuable planar space on the chip. The vertical FET architecture allows components to be stacked over each other, significantly reducing the footprint of the devices. Furthermore, the combination with BSPDN integrates electrostatic discharge (ESD) protection directly into this vertical structure. ESD protection can enhance safeguarding delicate electronic components against sudden spikes in power, which can cause irreparable damage. By vertically integrating ESD diode strings within the BSPDN framework, the overall design not only conserves space but also enhances the efficiency and robustness of the power distribution throughout the device. Such a vertical integration strategy addresses the challenge of scaling down the size of the components and provides substantial area benefits. These advancements can facilitate the development of electronic devices, enabling higher functionality and performance within increasingly smaller dimensions.

Accordingly, the teachings herein provide methods and systems of semiconductor device formation with vFET architecture and BSPDN. The techniques described herein may be implemented in a number of ways. Example implementations are provided below with reference to the following figures.

### Example Semiconductor Device with vFET Structure and BSPDN

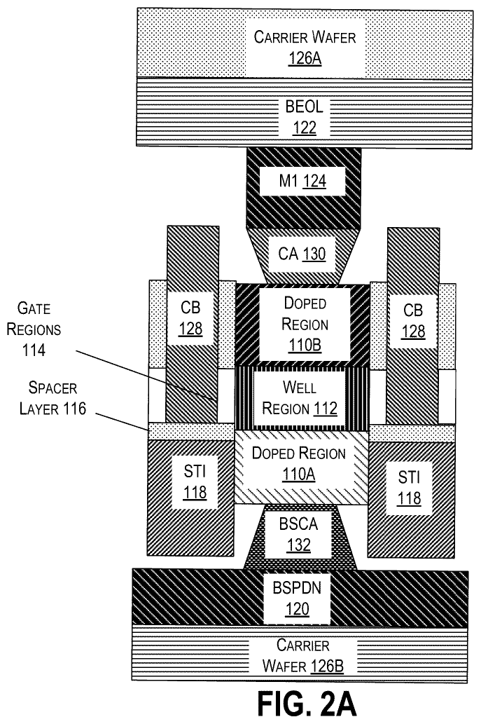

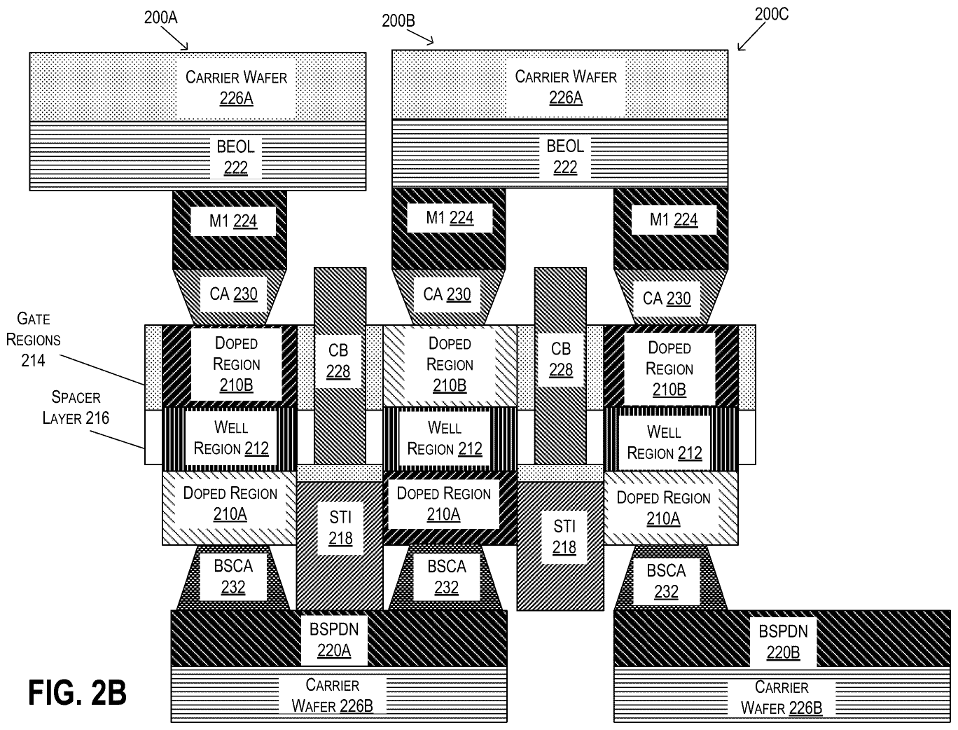

Reference now is made to FIGS. 2A-2B, which are simplified cross-section view of a semiconductor device, consistent with illustrative embodiments. Reference is now made to FIG. 2A, which illustrates a semiconductor device including a first doped region 110A, a second doped region 110B, a well region 112, gate regions 114, a spacer layer 116, shallow trench isolation, STI 118, a backside power delivery network, BSPDN 120, a back end of line, BEOL 122, a frontside wiring, M1 124, a frontside carrier wafer 126A, a backside carrier wafer 126B, gate contacts, CB 128, a frontside contact, CA 130, and a backside contact, BSCA 132.

The first doped region 110A can be located between two portions of the STI 118 and be doped with an N-type dopant or a P-type dopant. The doping process can define the electrical properties of the first doped region 110A such as the conductivity and behavior under different voltage conditions. The choice between N-type and P-type doping depends on the specific requirements of the device and the desired electrical characteristics. In some embodiments, the first doped region 110A can be in direct contact with the BSCA 132.

The well region 112 can be an N-well region or a P-well region. A P-well region can be formed by doping by a type P dopant, which introduces an excess of positive charge carriers (holes), and an N-well region can be formed by doping by a type N dopant, which introduces an excess of negative charge carriers (electrons).

The gate regions 114 serve as control elements that regulate the flow of current through the semiconductor device. The gate regions 114 can be composed of a conductive material. The gate regions 114 can control the flow of electric current across the channel region. In addition to acting as a switch, modulating the gate voltage can enable the gate regions 114 to control the current flowing through the channel region, resulting in amplified output signals.

In an embodiment, the gate regions 114 can enable the implementation of Boolean active operations, such as AND, OR, and NOT, by controlling the flow of current based on the input voltages. In some embodiments, the gate regions 114, along with other active device components, can facilitate the miniaturization and integration of electronic circuits. The ability to control the channel region's conductivity through the gate voltage allows for compact and highly efficient circuit designs.

The spacer layer 116, which can be an isolation layer, can cover, e.g., surround, the first doped region 110A. In some embodiments, the spacer layer 116 can isolate the STI 118 from contact with the gate regions 114 by covering a top surface of the STI 118.

The STI 118 can electrically isolate different components by filling the trenches with an insulating material, such as silicon dioxide. The STI 118 can prevent electrical interference and crosstalk between adjacent devices, ensuring that each component operates independently without affecting its neighbors. In some embodiments, the STI 118 includes an STI liner and an STI oxide. The STI liner can cover the bottom surface and sidewalls of the STI oxide and be made of SiN.

The BSPDN 120 can distribute power efficiently across the semiconductor device from the backside, which can complement the vertical architecture by saving lateral space. In some embodiments, the BSCA 132 is part of the BSPDN 120.

The BEOL 122 can include metal interconnects and other structures on the upper layers of the semiconductor device to form a network of connections that link various components of the semiconductor device.

The CA 130 located over the second doped region 110B can establish a connection between second doped regions 110B and the BEOL 122 through a set of vias and the M1 124. The CA 130 can ensure efficient electrical routing and connectivity within the semiconductor device. The fabrication of the CA 130 can involve lithography and etching processes to define the contact area. The CA 130 can be made using conductive materials such as copper (Cu) or tungsten (W).

The frontside carrier wafer 126A and the backside carrier wafer 126B can be used to support the wafers and avoid damages during processing, as handling and processing wafers without additional support can lead to breakage or warping, especially during high-temperature or precision processes. The frontside carrier wafer 126A and the backside carrier wafer 126B can function as mechanical supports. In some embodiments, the semiconductor device includes the frontside carrier wafer 126A. In some embodiments, the semiconductor device includes the frontside carrier wafer 126A and the backside carrier wafer 126B.

The CB 128 can serve as the electrical connections to the gate regions 114, allowing control over the flow of current between the gate channels. The CB 128 can be formed on top of the gate channels, and can be made of tungsten (W), aluminum (Al), or polysilicon.

The BSCA 132 can be a region on the backside of the semiconductor device where electrical connections are made. By establishing the electrical contacts, the BSCA 132 can ensure the proper functioning of the semiconductor device and facilitates electrical signal transmission. The BSCA 132 can serve as a thermal interface between the semiconductor device and a heat sink or other cooling mechanisms. By establishing direct contact with the substrate, the BSCA 132 can conduct the heat away from the semiconductor device, and contribute to improved thermal dissipation. In some embodiments, the BSCA 132 can help mitigate parasitic effects, such as substrate coupling or substrate noise, from the semiconductor device. In further embodiments, the BSCA 132 can allow for increased integration density in the semiconductor device.

The first doped region 110A, which is treated with specific impurities to adjust its electrical properties, enhancing conductivity or controlling the type of charge carriers. On top of this, a well region is positioned, which plays a critical role in the device's functionality. This well is typically lightly doped compared to the first doped region and is central to managing the movement and behavior of charge carriers within the semiconductor.

Reference is now made to FIG. 2B, which illustrates a semiconductor device including a first vertical diode 200A, a second vertical diode 200B and a third vertical diode 200C.

In some embodiments, the first vertical diode 200A and the second vertical diode 200B are electrically connected via a first BSPDN 220A, and the second vertical diode 200B and the third vertical diode 200C are electrically connected via a first frontside power wiring, M1 224A. Each of the first vertical diode 200A, the second vertical diode 200B and the third vertical diode 200C includes a first doped region 210A over a backside contact, BSCA 232, a well region 212 over the first doped region 210A, a second doped region 210B over the well region 212, gate regions 214 surrounding the well region 212, a spacer layer 216 surrounding the second doped region 210B, STI 218 surrounding the BSCA 232 and the first doped region 210A, a BEOL 222, a frontside carrier wafer 226A, a backside carrier wafer 226B, gate contacts, CB 228, and a frontside contact, CA 230.

The first doped region 210A can be located between two portions of the STI 218 and be doped with an N-type dopant or a P-type dopant. The doping process can define the electrical properties of the first doped region 210A such as the conductivity and behavior under different voltage conditions. The choice between N-type and P-type doping depends on the specific requirements of the device and the desired electrical characteristics. In some embodiments, the first doped region 210A can be in direct contact with the BSCA 232.

The well region 212 can be an N-well region or a P-well region. A P-well region can be formed by doping by a type P dopant, which introduces an excess of positive charge carriers (holes), and an N-well region can be formed by doping by a type N dopant, which introduces an excess of negative charge carriers (electrons).

The gate regions 214 can serve as control elements that regulate the flow of current through the semiconductor device. The gate regions 214 can be composed of a conductive material. The gate regions 214 can control the flow of electric current across the channel region. In addition to acting as a switch, modulating the gate voltage can enable the gate regions 214 to control the current flowing through the channel region, resulting in amplified output signals.

In an embodiment, the gate regions 214 can enable the implementation of Boolean active operations, such as AND, OR, and NOT, by controlling the flow of current based on the input voltages. In some embodiments, the gate regions 214, along with other active device components, can facilitate the miniaturization and integration of electronic circuits. The ability to control the channel region's conductivity through the gate voltage allows for compact and highly efficient circuit designs.

The spacer layer 216 can cover, e.g., surround, the first doped region 210A. In some embodiments, the spacer layer 216 can isolate the STI 218 from contact with the gate regions 214 by covering a top surface of the STI 218.

The STI 218 can electrically isolate different components by filling the trenches with an insulating material, such as silicon dioxide. The STI 218 can prevent electrical interference and crosstalk between adjacent devices, ensuring that each component operates independently without affecting its neighbors. In some embodiments, the STI 218 includes an STI liner and an STI oxide. The STI liner can cover the bottom surface and sidewalls of the STI oxide and be made of SiN. The STI 218 can be isolated from contact with the gate regions 214 via the spacer layer 216. The first vertical diode 200A can include a second frontside power wiring, M1 224B, and the third vertical diode 200C can include a second BSPDN 220B.

The first BSPDN 220A and the second BSPDN 220B can distribute power efficiently across the semiconductor device from the backside, which can complement the vertical architecture by saving lateral space.

The BEOL 222 can include metal interconnects and other structures on the upper layers of the semiconductor device to form a network of connections that link various components of the semiconductor device.

The CA 230 located over the second doped region 210B can establish a connection between second doped regions 210B and the BEOL 222 through a set of vias and the M1 224A. The CA 230 can ensure efficient electrical routing and connectivity within the semiconductor device. The fabrication of the CA 230 can involve lithography and etching processes to define the contact area. The CA 230 can be made using conductive materials such as copper (Cu) or tungsten (W).

The frontside carrier wafer 226A and the backside carrier wafer 226B can be used to support the wafers and avoid damages during processing, as handling and processing wafers without additional support can lead to breakage or warping, especially during high-temperature or precision processes. The frontside carrier wafer 226A and the backside carrier wafer 226B can function as mechanical supports.

The CB 228 can serve as the electrical connections to the gate regions 214, allowing control over the flow of current between the gate channels. The CB 228 can be formed on top of the gate channels, and can be made of tungsten (W), aluminum (Al), or polysilicon.

The BSCA 232 can be a region on the backside of the semiconductor device where electrical connections are made. By establishing the electrical contacts, the BSCA 232 can ensure the proper functioning of the semiconductor device and facilitates electrical signal transmission. The BSCA 232 can serve as a thermal interface between the semiconductor device and a heat sink or other cooling mechanisms. By establishing direct contact with the substrate, the BSCA 232 can conduct the heat away from the semiconductor device, and contribute to improved thermal dissipation. In some embodiments, the BSCA 232 can help mitigate parasitic effects, such as substrate coupling or substrate noise, from the semiconductor device. In further embodiments, the BSCA 232 can allow for increased integration density in the semiconductor device.

The first doped region 210A, which is treated with specific impurities to adjust its electrical properties, enhancing conductivity or controlling the type of charge carriers. On top of this, a well region is positioned, which plays a critical role in the device's functionality. This well is typically lightly doped compared to the first doped region and is central to managing the movement and behavior of charge carriers within the semiconductor.

In some embodiments, the M1 224 can be isolated by an interlayer dielectric (ILD, not shown), and the first BSPDN 220A and the second BSPDN 220B can be isolated by the ILD.

### Example Fabrication of a Semiconductor Device with vFET Structure and BSPDN

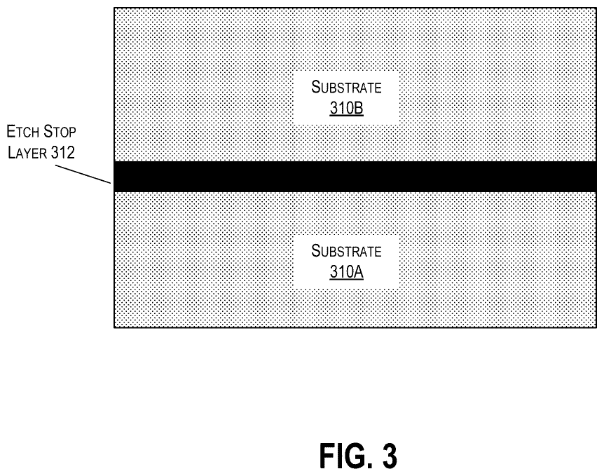

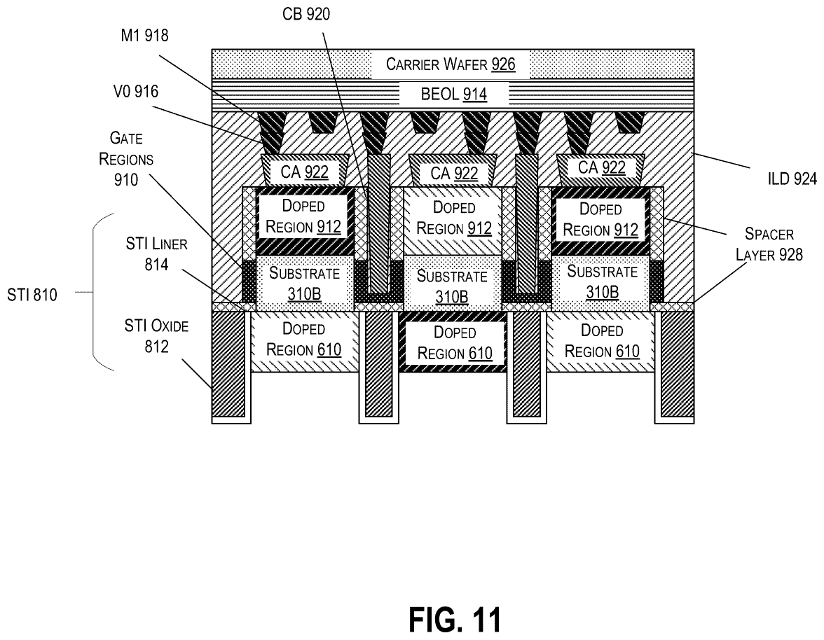

With the foregoing description of an example semiconductor device, it may be helpful to discuss an example process of manufacturing the same. To that end, FIGS. 3-13 illustrate various acts in the manufacture of a semiconductor device, consistent with illustrative embodiments.

Reference now is made to FIG. 3, which is a simplified cross-section view of a semiconductor device, after the preparation of the starting wafer, consistent with an illustrative embodiment. As noted above, the semiconductor device includes a first substrate 310A, a second substrate 310B, and an etch stop layer 312.

In the illustrative example depicted in FIG. 3, the semiconductor device is depicted as being on silicon as the first substrate 310A and the second substrate 310B, while it will be understood that other types as the first substrate 310A and the second substrate 310B can be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 310A and the second substrate 310B can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment, the substrate may be silicon with silicon oxide, nitride, or any other insulating film on top.

In various embodiments, the etch stop layer 312 is formed between the first substrate 310A and the second substrate 310B. The etch stop layer 312 can be a thin layer of material incorporated into the structure of the semiconductor device to provide a selective barrier against etching processes, preventing further removal of underlying materials during fabrication. The etch stop layer 312 can enable precise control over the etching depth and help define the desired device dimensions. The etch stop layer 312 can further provide a stopping point for the etching process, ensuring that specific layers or regions are not etched beyond a certain point, leading to accurate patterning and control of critical features. The etch stop layer 312 can create a distinct separation between different layers or components within the device structure, and prevent the undesired etching of underlying layers or materials, enabling the creation of complex, multi-layered structures with well-defined interfaces and boundaries. In some embodiments, the etch stop layer 312 acts as a protective barrier for sensitive or delicate materials to shield such materials from aggressive etchants, preventing damage or degradation during subsequent fabrication steps.

In some embodiments, prior to forming the etch stop layer 312, the first substrate 310A and/or the second substrate 310B is prepared by cleaning and removing any impurities or oxide layers. The etch stop layer 312 is deposited onto the first substrate 310A using techniques such as chemical vapor deposition (CVD), physical vapor deposition (PVD), or atomic layer deposition (ALD). In an embodiment, a photoresist can be applied, exposed to a patterned mask, developed, and used as a protective layer to define the etch stop regions. The etch stop layer 312 can then be selectively etched, stopping at a predetermined depth, while protecting the underlying layers. After the etching process, the remaining photoresist can be removed through stripping techniques. While in some embodiments, SiGe is used to form the etch stop layer 312, in some embodiments, silicon nitride (SiN), silicon oxide (SiO2), or silicon oxynitride (SiON) can be used as the etch stop layer 312.

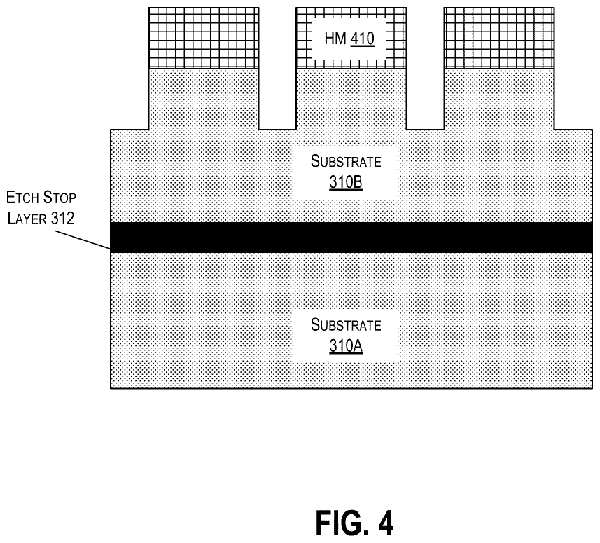

FIG. 4 illustrates the semiconductor device after the patterning of the fins, in accordance with some embodiments. In some embodiments, the fins are patterned by removing portions of the second substrate 310B. A hard mask, HM 410, is formed over the top surface of the fins.

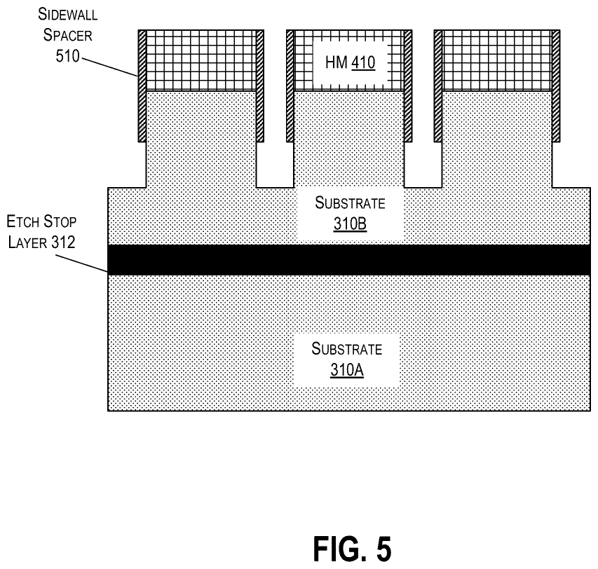

FIG. 5 illustrates the semiconductor device after the formation of the sidewall spacer, in accordance with some embodiments. In some embodiments, a sidewall spacer 510 is formed over the sidewalls of the fins. Consequently, the fins deepen by removing, e.g., etching, additional portions of the second substrate 310B.

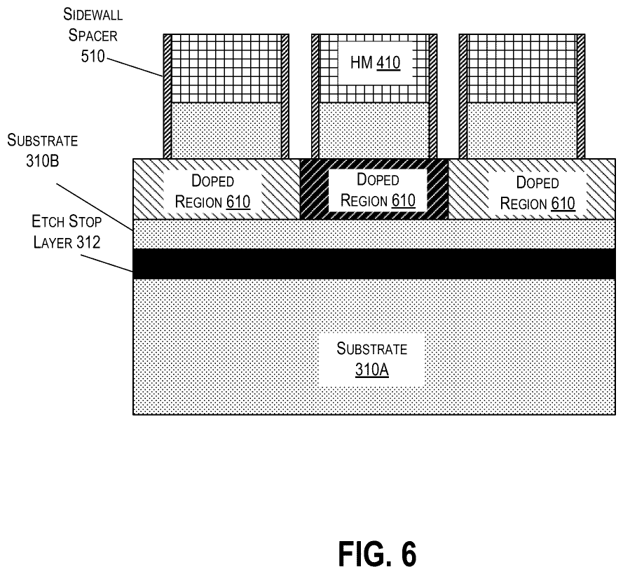

FIG. 6 illustrates the semiconductor device after the formation of the first doped regions, in accordance with some embodiments. In some embodiments, the first doped regions 610 are formed below the fins where the second substrate 310B is not covered by the sidewall spacer 510. A thermal annealing process can be used to enhance diffusion of the dopants into the first doped regions 610.

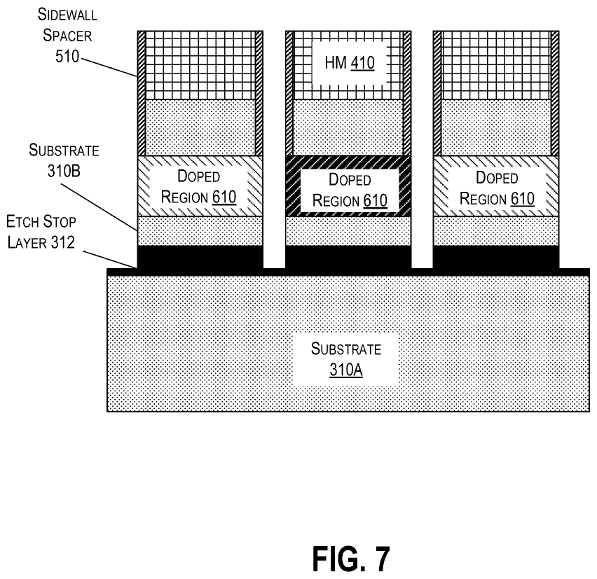

FIG. 7 illustrates the semiconductor device after the patterning of the active regions, in accordance with some embodiments. In some embodiments, portions of the first doped regions 610, the second substrate 310B and the etch stop layer 312 within the fins are removed. The removal process stops before the etch stop layer 312 is completely removed.

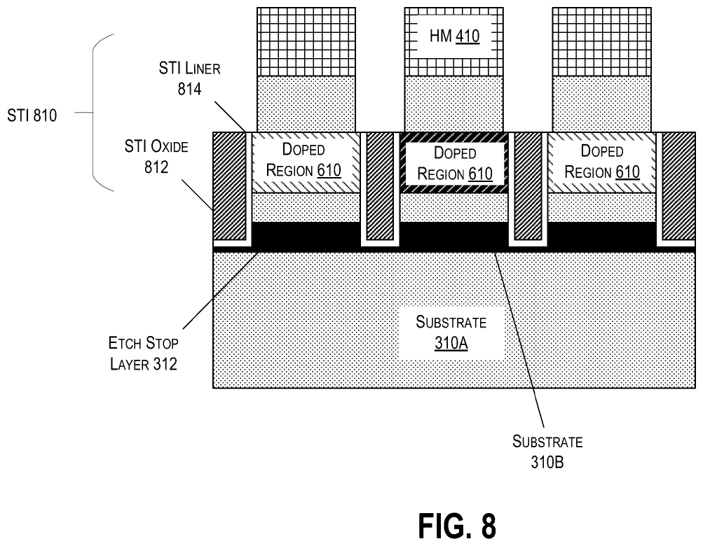

FIG. 8 illustrates the semiconductor device after the formation of the shallow trench isolation, in accordance with some embodiments. In some embodiments, STI 810 is formed by filling the removed portions of the first doped regions 610, the second substrate 310B and the etch stop layer 312 within the fins. To that end, a layer of STI oxide 812 is formed over the sidewalls of the fins and the upper surface of the exposed etch stop layer 312. An STI liner 814 can fill the remaining portions. In more details, the STI 810 can include the STI oxide 812 and the STI liner 814.

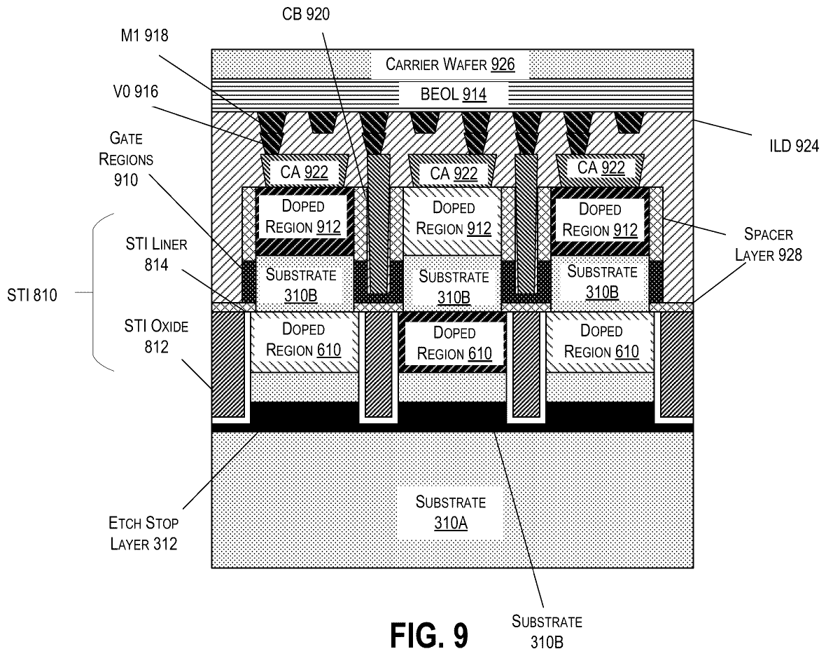

FIG. 9 illustrates the semiconductor device after the formation metal regions, the second doped regions, the middle of line processes, and the back end of line processes, in accordance with some embodiments. In some embodiments, the gate regions 910 can be formed by a replacement metal gate (RMG) process to fabricate metal gate electrodes. In some embodiments, RMG can involve the replacement of the SiGe with a metal material, which can offer improved electrical performance and scalability. The metal gates can provide electrostatic control of the channel region, reduce leakage currents, and improve the semiconductor device's performance. In some embodiments, the metal gates can further provide improved control over the work function, enable matching of threshold voltages, and reduce semiconductor device variability. The second doped regions 912 can be formed by replacing the hard mask. Gate contacts, CB 920, and front contacts, CA 922, can connect the gate regions 910 and the second doped regions 912, respectively, to a BEOL 914 through a set of vias, V0 916, and a frontside wiring, M1 918. A spacer layer 928 is formed over the STI 810 and between the second doped regions 912.

An ILD 924 can be formed surrounding the active regions and the middle of line components. The ILD 924 can be a layer of insulating material to electrically isolate and provide mechanical support between different layers of conducting and active components. The ILD 924 can enable efficient signal transmission, reduce crosstalk, and ensure the proper functioning of semiconductor device. In an embodiment, the ILD 924 can electrically isolate adjacent conducting layers or active components. By providing insulation between different layers, the ILD 924 can prevent electrical shorts, reduce (e.g., minimize) leakage current, and ensure that signals are directed only along the desired pathways. In some embodiments, the ILD 924 can help reduce parasitic capacitance between adjacent metal interconnects or active devices and provide mechanical support to the passive device's structure. In some embodiments, the BEOL 914 is formed over the ILD 924, followed by formation of the carrier wafer 926. The BEOL 914 can include metal interconnects, e.g., wires and metal lines, and insulating layers that connect the various components of the semiconductor device and enable them to function as a cohesive unit.

In various embodiments, carrier wafer bonding, also known as wafer-to-wafer bonding or chip-to-wafer bonding, is performed to join two semiconductor devices together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices. The metal layer can be deposited or transferred onto one or both semiconductor device surfaces, and the semiconductor devices can then be brought into contact and subjected to temperature and pressure to create a metallic bond.

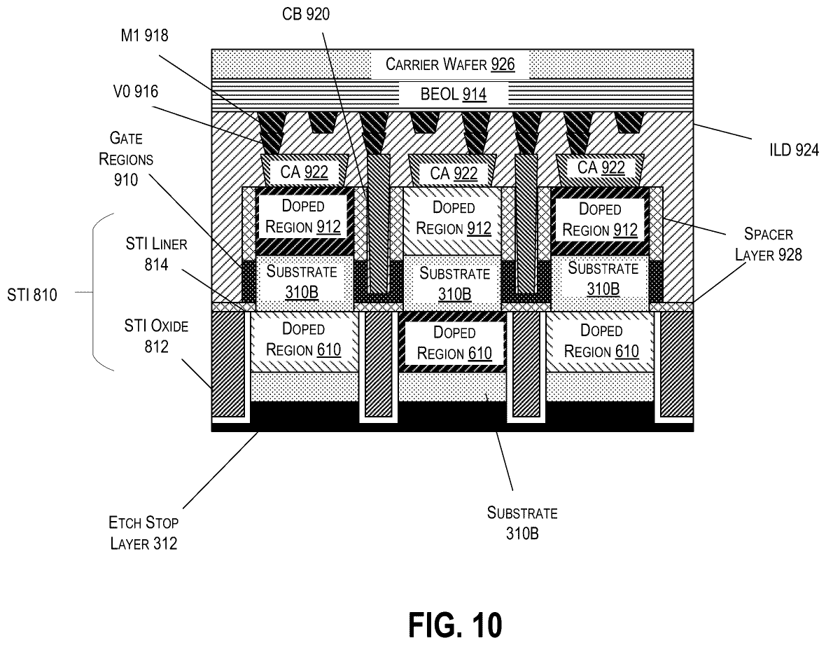

FIG. 10 illustrates the semiconductor device after the removal of the first substrate, in accordance with some embodiments. In some embodiments, the wafer is flipped and the first substrate is removed. The etching process can stop at the etch stop layer. It should be noted that, for the sake of simplicity, the semiconductor device is not shown as flipped.

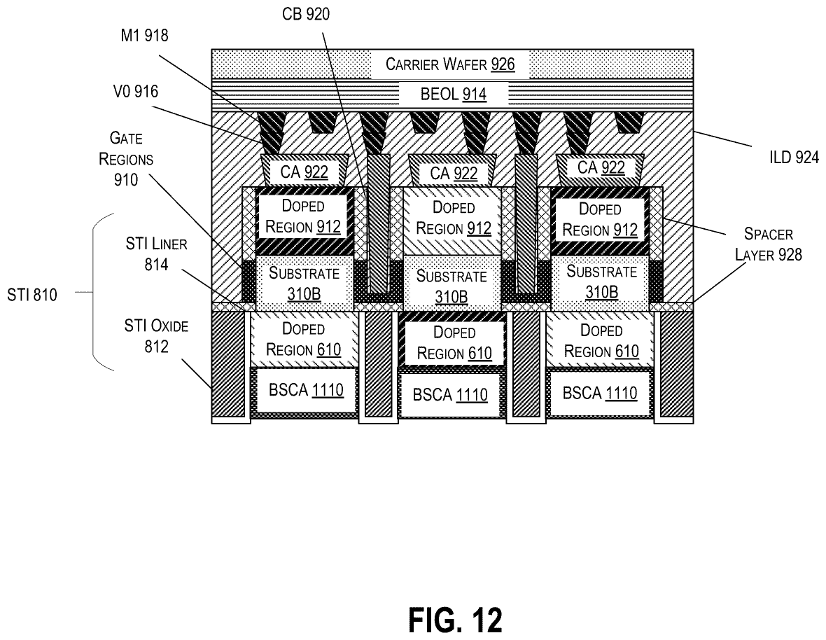

FIG. 12 illustrates the semiconductor device after the removal of the etch stop layer, in accordance with some embodiments. In some embodiments, the etch stop layer and the portions of the second substrate below the first doped regions 610 are removed and the first doped regions 610 and the STI 810 are exposed.

FIG. 12 illustrates a semiconductor device after the formation of the backside contact, in accordance with some embodiments. In some embodiments, the backside contacts, BSCA 1210, are formed.

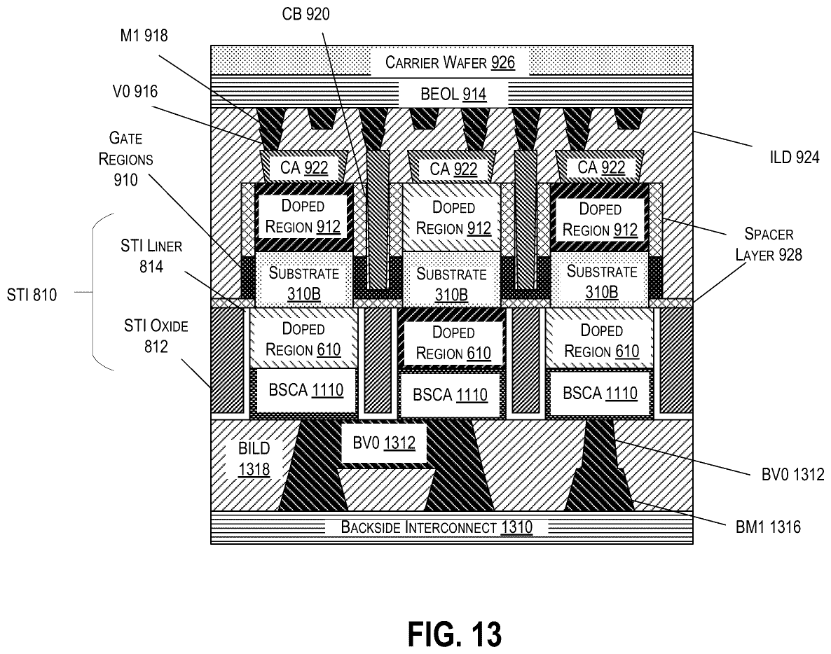

FIG. 13 illustrates a semiconductor device after the formation of a backside interconnect, in accordance with some embodiments. In some embodiments, the first vertical diode and the second vertical diode can be connected to a backside interconnect 1310 through a first backside via, BV0 1312, and a first backside power wiring, BM1 1314. The third vertical diode can be connected to the backside interconnect 1310 through a second backside via 1314 and a second backside power wiring, BM1 1316.

A bottom ILD, BILD 1318 is formed to isolate the BM1 1314 and the BM1 1316. In several embodiments, the BILD 1318 can provide structural support to the semiconductor device by maintaining the mechanical integrity and stability of the semiconductor device. The BILD 1318 can further help prevent the warping, bending, or cracking of the substrate, particularly during the manufacturing process or subsequent handling. The BILD 1318 can ensure that the semiconductor device remains mechanically robust and maintains its dimensional stability.

In an embodiment, the BILD 1318 can also serve as a planarization layer in the semiconductor device fabrication process. As various layers are deposited and patterned on the front side of the semiconductor device, irregularities or topographic variations may arise. The BILD 1318 can be used to smoothen the surface, creating a more planar substrate for subsequent processing steps, such as metal interconnect deposition or bonding. In some embodiments, a low dielectric constant BILD material can be utilized to reduce signal delays, crosstalk, and power consumption in high-speed and high-frequency circuits. By optimizing the dielectric constant, the BILD 1318 can contribute to improved overall semiconductor device performance. In several embodiments, BILD 1318 can facilitate wafer-level testing of the semiconductor device. By providing electrical isolation between the active regions and the backside contact, individual passive device or elements on the semiconductor device can be electrically accessed and tested without interference from neighboring devices or components. This enables efficient.

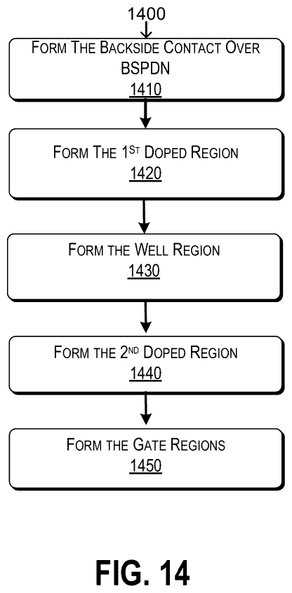

FIG. 14 illustrates a block diagram of a method 1400 for forming the semiconductor device, in accordance with some embodiments. As shown by block 1410, the backside contact over a backside power delivery network (BSPDN) is formed.

As shown by block 1420, the first doped region over the backside contact is formed.

As shown by block 1430, the well region over the first doped region is formed.

As shown by block 1440, the second doped region over the well region is formed.

As shown by block 1450, the gate regions surrounding the well region are formed.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a backside contact over a backside power delivery network (BSPDN);
a first doped region over the backside contact;
a well region over the first doped region;
a second doped region over the well region; and
gate regions surrounding the well region.

2. The semiconductor device of claim 1, wherein further comprising a spacer layer surrounding the second doped region.

3. The semiconductor device of claim 1, further comprising shallow trench isolation (STI) surrounding the backside contact and the first doped region.

4. The semiconductor device of claim 3, wherein the STI includes an STI oxide layer surrounded by an STI liner.

5. The semiconductor device of claim 4, wherein the STI is isolated from contact with the gate regions via a spacer layer.

6. The semiconductor device of claim 1, wherein the semiconductor device is a vertical diode.

7. The semiconductor device of claim 1, wherein the semiconductor device further comprises a back end of line (BEOL), wherein the BEOL is connected to the second doped region via a contact and frontside power wirings.

8. A method for fabrication of a semiconductor device, the method comprising:
forming a backside contact over a backside power delivery network (BSPDN);
forming a first doped region over the backside contact;
forming a well region over the first doped region;
forming a second doped region over the well region; and
forming gate regions surrounding the well region.

9. The method of claim 8, further comprising:
forming a contact over the second doped region;
forming frontside power wirings over the contact;
forming a back end of line (BEOL) over the frontside power wirings; and
establishing an electrical connection between the second doped region and the BEOL via the contact and the frontside power wirings.

10. The method of claim 8, further comprising surrounding the second doped region via a spacer layer.

11. The method of claim 8, further comprising surrounding the backside contact and the first doped region via shallow trench isolation (STI).

12. The method of claim 11, wherein the STI includes an STI oxide layer surrounded by an STI liner.

13. The method of claim 12, further comprising isolating the STI from contact with the gate regions via a spacer layer.

14. A semiconductor device comprising:
a first vertical diode;
a second vertical diode adjacent to the first vertical diode on a first side of the second vertical diode; and
a third vertical diode adjacent to the second vertical diode on a second side of the second vertical diode, wherein:
the first vertical diode and the second vertical diode are electrically connected via a first backside power delivery network (BSPDN), and
the second vertical diode and the third vertical diode are electrically connected via a first frontside power wiring.

15. The semiconductor device of claim 14, wherein each of the first vertical diode, the second vertical diode and the third vertical diode comprises:
a first doped region over a backside contact;
a well region over the first doped region;
a second doped region over the well region; and
gate regions surrounding the well region.

16. The semiconductor device of claim 15, wherein each of the first vertical diode, the second vertical diode and the third vertical diode comprises a spacer layer surrounding the second doped region.

17. The semiconductor device of claim 15, wherein each of the first vertical diode, the second vertical diode and the third vertical diode comprises shallow trench isolation (STI) surrounding the backside contact and the first doped region.

18. The semiconductor device of claim 17, wherein the STI includes an STI oxide layer surrounded by an STI liner, and wherein the STI is isolated from contact with the gate regions via a spacer layer.

19. The semiconductor device of claim 14, wherein:
the first vertical diode further comprises a second frontside power wiring, and the third vertical diode further comprises a second BSPDN.

20. The semiconductor device of claim 19, wherein:
the first frontside power wiring and the second frontside power wiring are isolated by an interlayer dielectric (ILD), and
the first BSPDN and the second BSPDN are isolated by the ILD.
